(19) United States
(12) Patent Application Publication
(10) Pub. No.: US 2014/0097417 A1
(43) Pub. Date: Apr. 10, 2014

(54) Flexible display and method for manufacturing the same

(71) Applicant: InnoLux Corporation, Miao-Li County (TW)

(72) Inventors: Yen-Shih LIN, Miao-Li County (TW); Yue-Shih JENG, Miao-Li County (TW)

(73) Assignee: InnoLux Corporation, Miao-Li County (TW)

(21) Appl. No.: 13/951,604

(22) Filed: Jul. 26, 2013

(30) Foreign Application Priority Data
Oct. 5, 2012 (TW) 101136833

(51) Int. Cl. H01L 51/52; H01L 51/56

(52) U.S. Cl. CPC H01L 51/52; H01L 51/56
USPC 257/40; 438/34

(57) ABSTRACT

A flexible display and a method for manufacturing the same are disclosed. The flexible display comprises a carrier; an interface layer disposed on a surface of the carrier; and an organic light-emitting diode layer disposed on the interface layer, wherein the interface layer has a thickness of 0.5 μm to 10 μm.

### BACKGROUND OF THE INVENTION

1. Field of the Invention

The present invention relates to a flexible display and a method for manufacturing the same, and more particularly to a flexible display with flexibility as well as heat-resistance and a method for manufacturing the same.

2. Description of Related Art

An organic light-emitting diode (OLED) is a display technology in which the organic semiconductor material and the light-emitting material are driven by an electric current to emit light. Compared with LCDs, OLEDs have the advantages of ultra-lightness, ultra-thinness (thickness of less than 1 mm), high brightness, large viewing angle (up to 170 degrees), no need for a backlight, low power consumption, fast response speed, high definition, low heat generation, superior shock resistance, low manufacturing cost, and flexibility, etc.

Currently, in the methods for manufacturing the OLED flexible display, a temperature-resisting plastic is commonly used as the material for the flexible substrate. For example, some specific polyimide materials can withstand an operating temperature of 450° C., and are suitable for use as the flexible substrate for a display. In addition, the flexible substrate needs to have a certain thickness (of approximately 10 to 100 μm), for the purpose of sufficient supporting and loading. However, this thickness requirement necessitates a higher cost than that of a glass substrate. Also, an equipment capable of precisely controlling the thickness of the substrate (such as a slit coating equipment) is necessary in the manufacture process to obtain a substrate having the desirable thickness, thus increasing additional process costs.

Accordingly, what is needed in the art is a method for manufacturing a flexible display, which may use the existing LCD equipments with appropriate tracking/removal techniques and use a flexible material as a main body of a supporting structure, thereby producing a flexible display with both flexibility and temperature-resisting resistance. As such, the cost of the materials and the process equipments may be significantly reduced.

### SUMMARY OF THE INVENTION

An object of the present invention is to provide a flexible display having both flexibility and temperature-resisting resistance and a method for manufacturing the same to significantly reduce the cost of the materials and the process equipments.

To achieve the above object, the present invention provides a flexible display comprising a carrier; an interface layer disposed on a surface of the carrier; and an organic light-emitting diode layer disposed on the interface layer, wherein the interface layer has a thickness of 0.5 μm to 10 μm.

The flexible display of the present invention may further comprise: a thin film transistor layer disposed between the interface layer and the organic light-emitting diode layer; a second carrier disposed on the organic light-emitting diode layer; and a second interface layer disposed between the organic light-emitting diode layer and the second carrier, wherein the second interface layer has a thickness of 0.5 μm to 10 μm. Also, the flexible display of the present invention may further comprise a color filter disposed between the organic light-emitting diode layer and the second interface layer.

The present invention provides a method for manufacturing a flexible display comprising (A) providing a substrate; (B) forming a first interface layer on a surface of the substrate, wherein the first interface layer has a thickness of 0.5 μm to 10 μm; (C) forming an organic light-emitting diode layer on the first interface layer; and (D) removing the substrate and replacing the same with a carrier, wherein, before the step (C), the method may further comprise forming a thin film transistor layer on the first interface layer and optionally forming a second interface layer on the organic light-emitting diode layer.

Alternatively, the method for manufacturing a flexible display comprises (A) providing a first substrate and a second substrate; (B) forming a first interface layer and a second interface layer on a surface of the first substrate and a surface of the second substrate respectively, wherein at least one of the first interface layer and the second interface layer has a thickness of 0.5 μm to 10 μm; (C) forming sequentially a thin film transistor layer and an organic light-emitting diode layer on the first interface layer and forming a color filter on the second interface layer; (D) disposing the second substrate with the color filter thereon opposite to the first substrate with the organic light-emitting diode layer thereon, such that the color filter is disposed on the organic light-emitting diode layer; and (E) removing the first substrate and replacing the same with a fist carrier and removing the second substrate and replacing the same with a second carrier. The method may be used, for example, to prepare a white organic light-emitting diode (white OLED) display, in which a color filter is required.

Hereafter, the term “carrier” not only refers to the carrier, but also to the first and the second carriers; the term “interface layer” not only refers to the interface layer, but also to the first and the second interface layers; and the term “substrate” not only refers to the substrate, but also to the first and the second substrates.

In the above method for manufacturing a flexible display, both the first and the second carriers are not particularly limited, and those contributing to increase component support and/or combined with additional features may be used depending on the device requirements, for example, a plastic plate, a touch film, a cover lens, a hard coat film, or combinations thereof. Examples of the plastic plate may be polyethylene terephthalate (PET), polymethyl methacrylate (PMMA), or combinations thereof.

In the present invention, the interface layer preferably has a preferable thickness of 1 μm to 5 μm, more preferably 1 μm to 3 μm, and the thickness may be adjusted by those of ordinary skill in the art depending on the requirement of the actual devices and the performance of the process equipment. For example, when two or more interface layers are included, the interface layers may have different thicknesses.

In the present invention, the tolerance temperature of the temperature-resisting interface layer is not particularly limited, as long as it is capable of withstanding a temperature-resisting process without damage and deformation, and preferably 450° C. or above. Thus, the interface layer may be a plastic material, such as polyimide; an inorganic material, such as silicon nitride, or gallium nitride; or a combination of a plastic material and an inorganic material, but the present invention is not limited thereto, and any material that comply with the requirement of the temperature-resistance may be used.

In addition, the interface layer may be formed by roller printing or coating using any conventional techniques before thermal curing. Alternatively, the interface layer may be formed using the evaporation coating. Furthermore, the substrate may be removed using any conventional techniques, such as laser or cutting tool. In addition, the type of the substrate is not limited, preferably a glass substrate, or any substrate commonly used in the art.

Also, the thin film transistor and the organic light-emitting diode layer may be packaged, and the package may be realized using any conventional techniques, for example, lamination of an adhesive plastic substrate, or evaporation of a package material.

### BRIEF DESCRIPTION OF THE DRAWINGS

FIGS. 1A to 1G show a process flow of the preparation of the flexible display according to a preferable embodiment of the present invention.

FIGS. 2A to 2E show a process flow of the preparation of the flexible display according to another preferable embodiment of the present invention.

FIGS. 3A to 3D show a process flow of the preparation of the flexible display according to also another preferable embodiment of the present invention.

### DETAILED DESCRIPTION OF THE PREFERRED EMBODIMENT

### Embodiment 1

### Preparation of White Organic Light-Emitting Diode (White OLED) Display

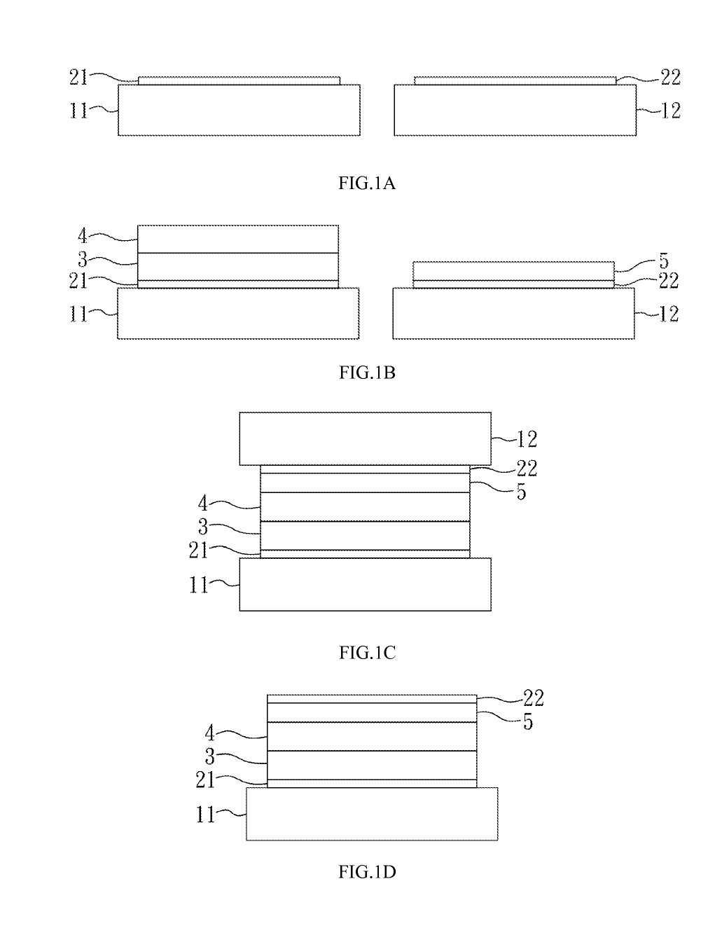

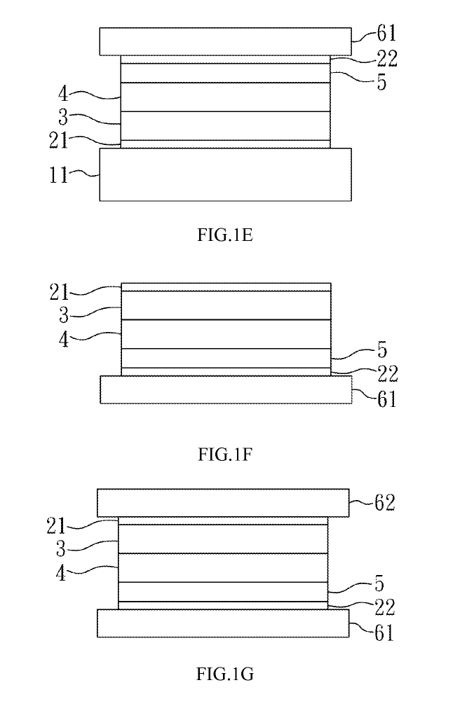

Referring to FIGS. 1A to 1G, a process flow of the preparation of the flexible display according to Embodiment 1 is illustrated.

First, as shown in FIG. 1A, two substrates 11, 12 are provided, wherein the substrates 11, 12 may be glass, and two interface layers 21, 22 are formed by covering the substrates 11, 12 respectively with a heat-resistant interface material (such as polyimide, silicon nitride, gallium nitride, or combinations thereof) using roller printing (such as relief printing with APR plate) or evaporation coating. At least one of the interface layers 21, 22 has a thickness of 0.5 μm to 10 μm, preferably 1 μm to 5 μm, and more preferably 1 μm to 3 μm. A multilayer roll printing may be optionally employed to increase the thickness of the interface layers.

Next, as shown in FIG. 1B, a thin film transistor layer 3 and an organic light-emitting diode layer 4 are sequentially formed on the substrate 11 with the interface layer 21 formed thereon; and a color filter 5 is formed on the substrate 12 with the interface layer 22 formed thereon.

Then, as shown in FIG. 1C, the substrate 12 with the color filter 5 formed thereon and the first substrate 11 with the organic light-emitting diode layer 4 formed thereon are disposed oppositely, such that the color filter 5 is disposed on the organic light-emitting diode layer 4.

Finally, as shown in FIG. 1D, the substrate 12 is removed by laser or cutting tool, and replaced with a carrier 61 (shown in FIG. 1E). Further, as shown in FIGS. 1F-1G, the first substrate 11 is removed by laser or cutting tool, and replaced with a carrier 62. The carriers 61, 62 may be a touch film, a cover lens, a hard coat film, or combinations thereof, and the material of the carriers may be a plastic plate, such as polyethylene terephthalate (PET), polymethyl methacrylate (PMMA), or combinations thereof.

Through the above steps, a laminated structure of the white organic light-emitting diode (white OLED) display may be obtained (shown in FIG. 1G), where the laminated structure includes the carrier 62, the interface layer 21, the thin film transistor layer 3, the organic light-emitting diode layer 4, the color filter 5, the interface layer 22, and the carrier 61.

### Embodiment 2

### Preparation of Side-By-Side Organic Light-Emitting Diode Display

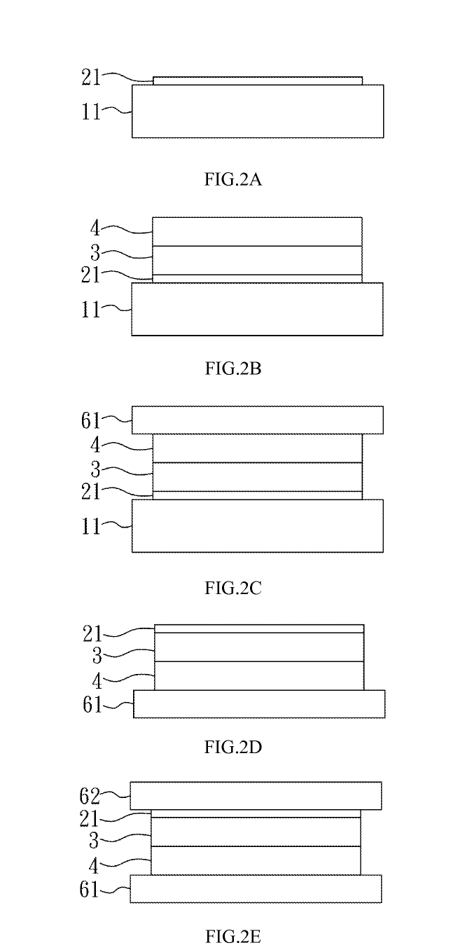

Referring to FIGS. 2A to 2E, a process flow of the preparation of the flexible display according to Embodiment 2 is illustrated.

First, as shown in FIG. 2A, a substrate 11 is provided, wherein the substrate 11 may be glass, and an interface layer 21 is formed by covering the substrate 11 with a heat-resistant interface material (such as polyimide, silicon nitride, gallium nitride, or combinations thereof) using roller printing (such as relief printing with APR plate) or evaporation coating. The interface layer 21 has a thickness of 0.5 μm to 10 μm, preferably 1 μm to 5 μm, and more preferably 1 μm to 3 μm. A multilayer roll printing may be optionally employed to increase the thickness of the interface layer.

Next, as shown in FIG. 2B, a thin film transistor layer 3 and an organic light-emitting diode layer 4 are sequentially formed on the substrate 11 with the interface layer 21 formed thereon; and then, a carrier 61 is disposed on the organic light-emitting diode layer 4, as shown in FIG. 2C.

Finally, as shown in FIG. 2D, the substrate 11 is removed by laser or cutting tool, and replaced with a carrier 62 (as shown in FIG. 2E). The carrier 61 and the carrier 62 may be a touch film, a cover lens, a hard coat film, or combinations thereof, and the material of the carrier may be a plastic plate, such as polyethylene terephthalate (PET), polymethyl methacrylate (PMMA), or combinations thereof.

Through the above steps, a laminated structure of the side-by-side organic light-emitting diode may be obtained (as shown in FIG. 2E), where the laminated structure includes the carrier 62, the interface layer 21, the thin film transistor layer 3, the organic light-emitting diode layer 4, and the carrier 61 in order.

### Embodiment 3

### Preparation of Side-By-Side Organic Light-Emitting Diode Display

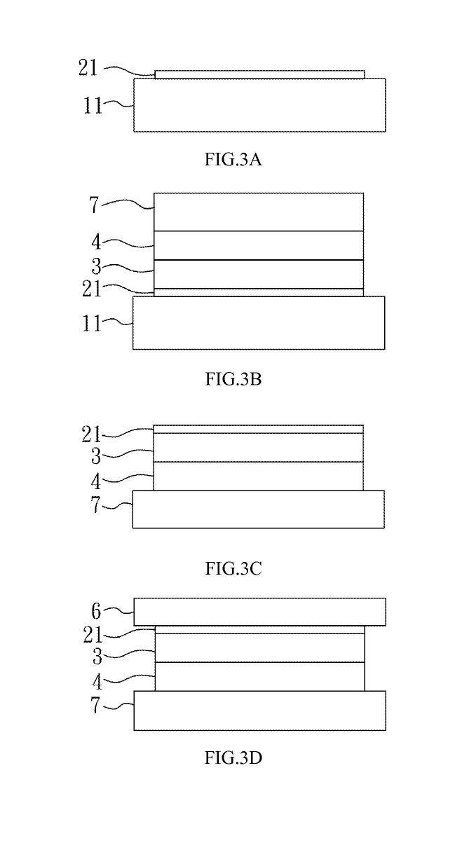

Referring to FIGS. 3A to 3D, a process flow of the preparation of the flexible display according to Embodiment 3 is illustrated.

First, as shown in FIG. 3A, a substrate 11 is provided, wherein the substrate 11 may be glass, and an interface layer 21 is formed by covering the substrate 11 with a heat-resistant interface material (such as polyimide, silicon nitride, gallium nitride, or combinations thereof) using roller printing (such as relief printing with APR plate) or evaporation coating. The interface layer 21 has a thickness of 0.5 μm to 10 μm, preferably 1 μm to 5 μm, and more preferably 1 μm to 3 μm. A multilayer roll printing may be optionally employed to increase the thickness of the interface layers.

Next, as shown in FIG. 3B, a thin film transistor layer 3, an organic light-emitting diode layer 4, and a package layer 7 having a thickness of about 10 to 30 μm are sequentially formed on the substrate 11 with the interface layer 21 formed thereon.

After that, as shown in FIG. 3C, since the package layer has a sufficient thickness as a support, the substrate 11 may be removed directly by laser or cutting tool, and replaced with a carrier 6 (as shown in FIG. 3D). The carrier 6 may be a touch film, a cover lens, a hard coat film, or combinations thereof, and the material of the carrier may be a plastic plate, such as polyethylene terephthalate (PET), polymethyl methacrylate (PMMA), or combinations thereof.

Through the above steps, a laminated structure of the side-by-side organic light-emitting diode display may be obtained (as shown in FIG. 3D), where the laminated structure includes the carrier 6, the interface layer 21, the thin film transistor layer 3, the organic light-emitting diode layer 4, and the package layer 7 in order.

Therefore, through the present method for manufacturing a flexible display, the super thin interface layer is employed to avoid the use of expensive heat-resistant material for the flexible substrate, and it is not necessary to purchase expensive precision coating equipment, thereby significantly reducing the cost of the materials and the process equipments.

While the invention has been described in detail and with reference to specific embodiments thereof, it is to be understood that the foregoing description is exemplary and explanatory in nature and is intended to illustrate the invention and its preferred embodiments. Through routine experimentation, one skilled in the art will readily recognize that various changes and modifications can be made therein without departing from the spirit and scope of the invention. Thus, the invention is intended to be defined not by the above description, but by the following claims and their equivalents.

What is claimed is:

1. A flexible display comprising:
a carrier;
an interface layer disposed on a surface of the carrier; and
an organic light-emitting diode layer disposed on the interface layer, wherein the interface layer has a thickness of 0.5 μm to 10 μm.

2. The flexible display of claim 1, wherein the interface layer has a tolerance temperature of 450° C. or above.

3. The flexible display of claim 1, wherein the interface layer comprises polyimide, silicon nitride, gallium nitride, or combinations thereof.

4. The flexible display of claim 1, wherein the carrier is a plastic plate, a touch film, a cover lens, a hard coat film, or combinations thereof.

5. A method for manufacturing a flexible display comprising:
(A) providing a substrate;
(B) forming an interface layer on a surface of the substrate, wherein the interface layer has a thickness of 0.5 μm to 10 μm;
(C) forming an organic light-emitting diode layer on the interface layer; and
(D) removing the substrate and replacing the same with a carrier.

6. The method for manufacturing a flexible display of claim 5, wherein the carrier is plastic plate, touch film, a cover lens, a hard coat film, or combinations thereof.

7. The method for manufacturing a flexible display of claim 5, wherein the interface layer comprises polyimide, silicon nitride, gallium nitride, or combinations thereof.

8. A method for manufacturing a flexible display comprising the steps of:
(A) providing a first substrate and a second substrate;
(B) forming a first interface layer and a second interface layer respectively on a surface of the first substrate and a surface of the second substrate, wherein at least one of the first interface layer and the second interface layer has a thickness of 0.5 μm to 10 μm;
(C) forming a thin film transistor layer and an organic light-emitting diode layer sequentially on the first interface layer and forming a color filter on the second interface layer;
(D) disposing the second substrate with the color filter thereon and the first substrate with the organic light-emitting diode layer thereon oppositely such that the color filter is disposed on the organic light-emitting diode layer; and
(E) removing the first substrate to replace with a first carrier and removing the second substrate to replace the same with a second carrier.

9. The method for manufacturing a flexible display of claim 8, wherein at least one of the first carrier and the second carrier is a plastic plate, a touch film, a cover lens, a hard coat film, or combinations thereof.

10. The method for manufacturing a flexible display of claim 8, wherein each of the first interface layer and the second interface layer comprises polyimide, silicon nitride, gallium nitride, or combinations thereof.
